(19) United States
(12) Patent Application Publication
(10) Pub. No.: US 2023/0307166 A1
(43) Pub. Date: Sep. 28, 2023

(54) COIL WITH NON-UNIFORM TRACE

(71) Applicant: DSBJ PTE. LTD., Singapore (SG)

(72) Inventor: Soheil SAADAT, Irvine, CA (US)

(21) Appl. No.: 18/023,635

(22) PCT Filed: Feb. 25, 2021
(86) PCT No.: PCT/US2021/019659

§ 371 Date: Feb. 27, 2023

Related U.S. Application Data
(60) Provisional application No. 63/077,824, filed on Sep. 14, 2020.

(51) Int. Cl. H01F 17/00; H02J 50/12; H05K 1/03

(52) U.S. Cl. CPC H01F 17/0013; H02J 50/12; H05K 1/0393; H01F 2017/004; H01F 2017/006; H01F 2017/0073; H05K 2201/098

(57) ABSTRACT

A coil device includes a first conductor in a first layer and including a spiral shape and a second conductor in the first layer connected in parallel with the first conductor and extending adjacent to and parallel or substantially parallel to the first conductor. A cross-sectional area of the first conductor and a cross-sectional area of the second conductor are different.

### RELATED APPLICATIONS

This application claims the benefit of United States Provisional Patent Application No. 63/077,824, filed Sep. 14, 2020, the entire contents of which are hereby incorporated by reference for all purposes as if fully set forth herein.

### BACKGROUND OF THE INVENTION

### 1. Field of the Invention

The present invention relates to coils. More specifically, the present invention relates to coils with non-uniform trace geometry in a substrate, such as a flexible printed circuit (FPC), a printed circuit board (PCB), or silicon wafer that can be used in electronic device applications.

### 2. Description of the Related Art

Conventional coils include a continuous round copper wire formed in a spiral shape. Conventional coils can include a wire with a uniform diameter or can include traces with uniform widths and heights throughout the coil. As shown in FIGS. 1 and 2, conventional coils like coils 100 and 200 can have different shapes, such as circular, spiral, square, rectangular, and the like. The wires have a shielding insulation or coating on the wires’ outer surface that allows them to have a small spacing between each adjacent turn without creating a short circuit. As a result, conventional coils like coils 100 and 200 shown in FIGS. 1 and 2 have a relatively low resistance.

Using wires with a uniform diameter or using traces with uniform widths and heights simplifies design of conventional coils and provides conventional coils with good performance. But such conventional coils do not provide the best efficiency or performance. Such conventional coils are not always suitable for device integration due to the space limitations in cell phones, tablets, and other electronic devices.

The performance of conventional coils with uniform trace widths suffers from ‘proximity effect’ in which adjacent traces that are transmitting current in the same direction can push the current onto neighboring traces farther away from the nearby surfaces due to a generated Electro-Magnetic Force (EMF), creating a narrower path for the current to pass through each conductor. This phenomenon is illustrated in FIGS. 3A and 3B.

FIG. 3A shows a cross section of two adjacent wires 310 and 320 having a circular diameter and carrying current in the same direction. FIG. 3B shows a cross section of two adjacent wires 330 and 340 having a rectangular cross section and carrying current in the same direction. The shading represents the current density within the wires 310, 320, 330, and 340. As shown in FIGS. 3A and 3B, the current density of the wires 310, 320, 330, and 340 is higher in portions of the cross section that are farthest from the adjacent wire. This phenomenon compacts the current into a smaller portion of the wires 310, 320, 330, and 340 than the full cross-sectional area. As a result, the effective cross-sectional area decreases, and the current will be subject to a higher resistance path. Thus, the proximity effect can significantly increase the alternating current resistance of adjacent conductors as compared to the resistance of the adjacent conductors from direct current. The proximity effect increases as frequency increases.

### SUMMARY OF THE INVENTION

To overcome the problems described above, preferred embodiments of the present invention provide symmetrical coils with non-uniform trace widths in a flexible printed circuit that can be used in electronic-device applications.

There are many electronic-device applications that require high-efficiency coils including wireless charging systems for transferring power (e.g., automobiles and consumer electronics) electronic modules (e.g., integrated circuits (ICs) and PCBs), radio frequency (RF) components (e.g., filters), and the like. One of the challenges of making high quality coils is that the coils often need special materials or advanced processing techniques which adversely affect the cost and ability to mass produce. New techniques in coil design and manufacturing can be used to modify conventional coils and improve quality and performance. These changes include creating traces with non-uniform widths in a parallel configuration. The coil designs are usually application-specific because they often depend on coil geometry and/or frequency range of the circuitry.

According to a preferred embodiment of the present invention, a coil device includes a first conductor in a first layer and including a spiral shape and a second conductor in the first layer connected in parallel with the first conductor and extending adjacent to and parallel or substantially parallel to the first conductor. A cross-sectional area of the first conductor and a cross-sectional area of the second conductor are different.

The first conductor and the second conductor can have a rectangular cross section, and the spiral shape can be a circular spiral shape or a rectangular spiral shape.

A height of the first conductor can be equal to or substantially equal to a height of the second conductor, and a width of the first conductor and a width of the second conductor can be different. A height-to-width ratio of the first conductor and a height-to-width ratio of the second conductor can be different.

The coil device can further include a substrate; a third conductor in a second layer connected in parallel with the first conductor overlapping the first conductor in a plan view, the second layer is on an opposite side of the substrate as the first layer; and a fourth conductor in the second layer connected in parallel with the third conductor and overlapping the second conductor in the plan view, and extending adjacent to and parallel or substantially parallel to the third conductor. Height-to-width ratios of the first conductor and the third conductor can be equal or substantially equal. Height-to-width ratios of the second conductor and the fourth conductor can be equal or substantially equal. The height-to-width ratios of the first conductor and the third conductor and the height-to-width ratios of the second conductor and the fourth conductor can be different.

The substrate can be a flexible printed circuit or a printed circuit board.

According to a preferred embodiment of the present invention, a coil device includes a substrate; a first conductor in a first layer on the substrate and including a spiral shape; and a second conductor in a second layer on an opposite side of the substrate as the first layer, connected in parallel with the first conductor, and overlapping or substantially overlapping all of the first conductor in a plan view. A cross-sectional shape of the first conductor and a cross-sectional shape of the second conductor are identical or substantially identical.

The substrate can be a flexible printed circuit or a printed circuit board that includes the first layer and the second layer.

The coil device can further include a third conductor in the first layer, including a spiral shape, and connected to ends of the first conductor and the second conductor. The coil device can further include a third conductor in the first layer, including a spiral shape, and connected to an end of the first conductor; and a fourth conductor in the first layer, including a spiral shape, and connected to an end of the second conductor, wherein cross-sectional areas of the third and the fourth conductors can be identical or substantially identical.

The coil device can further include a third conductor in the first layer connected in parallel with the first conductor and extending adjacent to and parallel or substantially parallel to the first conductor and a fourth conductor in the second layer connected in parallel with the second conductor and extending adjacent to and parallel or substantially parallel to the first conductor, wherein the third conductor and the fourth conductor can overlap or can substantially overlap each other in the plan view. A cross-sectional shape of the third conductor and a cross-sectional shape of the fourth conductor can be identical or substantially identical. The cross-sectional shape of the third conductor and the cross-sectional shape of the first conductor can be different.

According to a preferred embodiment of the present invention, a device includes a substrate and a coil on a first surface of the substrate, having a spiral shape, and including first and second traces. The first and the second traces are connected in parallel and have different cross-sectional shapes along a least a portion of the length of the coil.

The coil can further include a third trace on the first surface of the substrate that is connected in parallel with the first and the second traces, and the first, the second, and the third traces can have different cross-sectional shapes. Widths of the first, the second, and the third traces can increase in a width direction of a cross section of the coil. The coil can further include third and fourth traces on a second surface of the substrate opposite to the first surface that are connected in parallel with the first and the second traces, the first and the third traces can have identical or substantially identical cross-sectional shapes, and the second and the fourth traces can have identical or substantially identical cross-sectional shapes. The number of traces in the coil can change over the length of the coil and/or the cross-sectional areas of the first and second traces can change over the length of the coil.

According to a preferred embodiment of the present invention, an electronic device includes the coil device according to one of the various other preferred embodiments of the present invention.

The above and other features, elements, characteristics, steps, and advantages of the present invention will become more apparent from the following detailed description of preferred embodiments of the present invention with reference to the attached drawings.

### BRIEF DESCRIPTION OF THE DRAWINGS

FIGS. 1 and 2 show shapes of coils of the related art.

FIGS. 3A and 3B are cross-sectional views showing current density in coils of the related art.

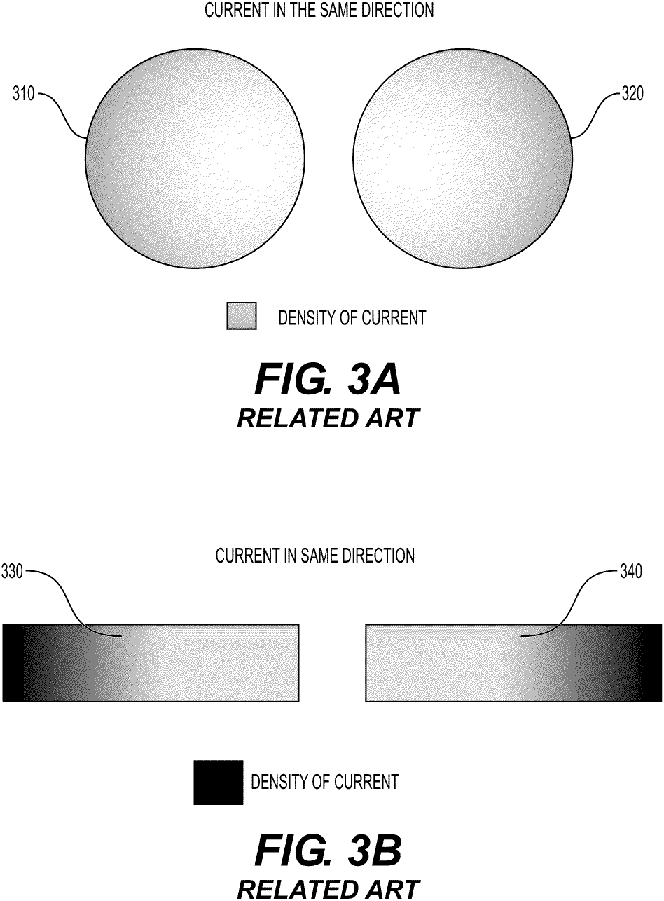

FIGS. 4A-4C show coil-trace geometries of comparative examples and inventive examples according to preferred embodiments of the present invention.

FIG. 5 shows a transmitter-receiver coil pair.

FIG. 6 shows a conventional coil with a uniform trace, and coils with non-uniform traces according to preferred embodiments of the present invention.

### DETAILED DESCRIPTION OF PREFERRED EMBODIMENTS

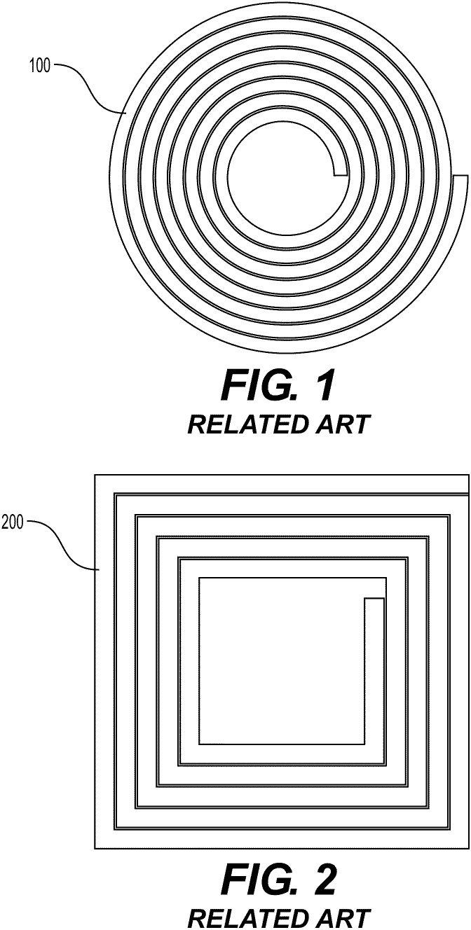

A coil on a substrate, such as a flexible printed circuit (FPC), a printed circuit board (PCB), or silicon wafer significantly reduces or minimizes required space and achieves significantly increased maximum efficiency in small-electronic-device applications, such as cell phones, tablets, etc. In an FPC coil, the conventional round insulated copper wire is replaced by traces or conductors with rectangular cross-sections that can be more simply fabricated. The traces can be formed in either circular shapes as shown in FIG. 1 or in rectangular shapes as shown in FIG. 2. FPC coils are much more versatile in terms of design, and multiple shapes are possible without forming or kinking round wires. If a lower resistance is desired, it is also simpler to make a multilayer-FPC coil than a multilayer-round-wire coil.

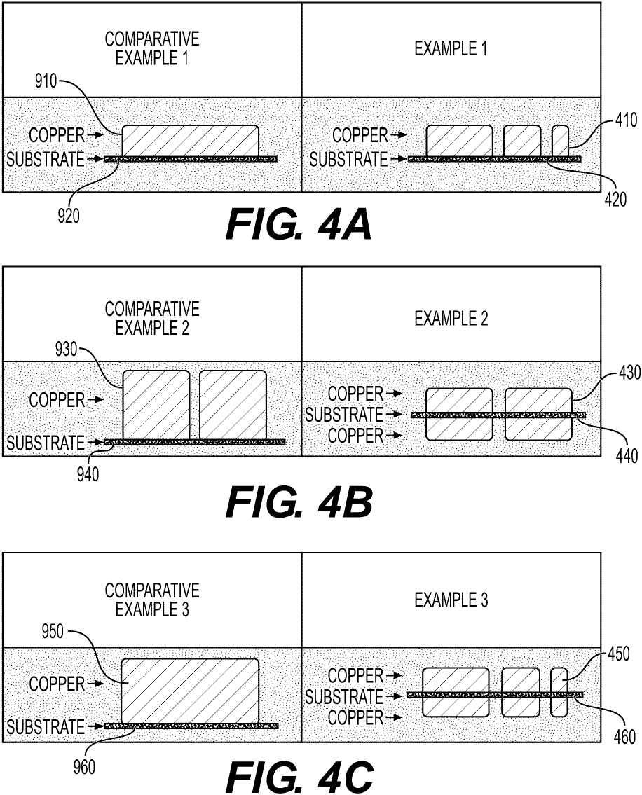

Additionally, patterning a trace into smaller traces with non-uniform widths can lower the electro-magnetic force between the traces, which in turn leads to a lower AC resistance and hence a reduction in the amount of generated heat with increased efficiency. For example, heat can be decreased by up to 5% and efficiency can be increased up to 5%. Often, coils with a single trace having a single consistent width along the entire length of the trace generate more heat around the center loops between the inner and outer loops, and conventional designs often need additional layers such as graphite to dissipate the heat concentrated in those areas. Splitting a trace into multiple traces with non-uniform widths can be more effective in reducing the coil resistance, which is the direct result of EMF reduction between different traces, than patterning traces with uniform widths. For example, splitting a trace into multiple traces can result in an up to 7% reduction in coil resistance compared to a coil with a single uniform trace width. Splitting a trace into multiple traces is shown in FIGS. 4A-4C. Splitting a trace into multiple traces can result in multiple traces that extend adjacent to and parallel or substantially parallel within manufacturing tolerances to each other.

FIGS. 4A-4C show cross sections of Comparative Examples 1-3 with uniform traces and Examples 1-3 of non-uniform traces according to preferred embodiments of the present invention. FIG. 4A shows Comparative Example 1 that includes a coil with trace 910 having a rectangular cross section on a substrate 920. Example 1 shows that a coil can be patterned into three separate traces 410 with non-uniform widths on a substrate 420. The cross-sectional area of trace 910 and the total cross-sectional area of traces 410 can be the same or substantially the same within manufacturing tolerances. For example, the width of trace 910 and the total width of the traces 410 can be the same or substantially the same within manufacturing tolerances, and the height of traces 910 and 410 can be the same or substantially the same within manufacturing tolerances. The cross-sectional areas of the traces 410 can increase in a width direction of the coil. For example, the widths of the traces 410 can increase in a width direction of a cross-section of the coil.

Similarly, splitting the height of a single sided trace into a double-sided trace can also reduce the electro-magnetic forces between the traces, and therefore lower the AC resistance of the coil. FIG. 4B shows Comparative Example 2 that includes a coil with two adjacent traces 930 having the same rectangular cross section on a substrate 940. Example 2 shows that a coil can be patterned as separate double-sided traces 430 on two sides of a substrate 440. In other words, a coil can be patterned as a pair of double-sided traces, with one trace on top of the substrate 440 and another trace on the bottom of the substrate 440. Although not shown, the pair of the double-sided traces (top and bottom) can be connected in parallel. The cross-sectional area of one of traces 930 and the total cross-sectional area of one of pairs of double-sided traces 430 can be the same or substantially the same within manufacturing tolerances. For example, the width of trace 930 can be the same or substantially the same within manufacturing tolerances as the total width of traces 430 on the top or the bottom of the substrate 440, and the height of traces 930 can be twice or substantially twice within manufacturing tolerances of the height of traces 430. That is, each trace 430 extends from the substrate 440 half as far as the trace 930 extends from the substrate 940. As shown in FIG. 4B, the traces 430 on the top and the bottom of the substrate 440 can be mirror images or substantial mirror images within manufacturing tolerances about the substrate 460.

FIG. 4C shows Comparative Example 3 that includes the coil with the trace 950 on the substrate 960. Comparative Example 3 is similar to Comparative Example 1, but Comparative Examples 3 has a thicker trace. Example 3 shows that a coil can be patterned as six separate traces 450 with non-uniform widths and on two sides of a substrate 460, hence combining the concepts of Examples 1 and 2. Example 3 includes double-sided traces 450 with non-uniform widths. The total cross-sectional area of traces 450 can be the same or substantially the same within manufacturing tolerances or less than the cross-sectional area of trace 950. For example, the width of trace 950 can be the same or substantially the same within manufacturing tolerances as the total width of traces 450 on the top or the bottom of the substrate 460, and the height of trace 950 can be twice or substantially twice within manufacturing tolerances or more than of the height of traces 450. That is, each trace 450 extends from the substrate 460 half as far or less than the trace 950 extends from the substrate 960. As shown in FIG. 4C, the traces 450 on the top and the bottom of the substrate 460 can be mirror images about the substrate 460. The cross-sectional areas of the traces 450 can increase in a width direction of the coil. For example, the widths of the traces 450 can increase in a width direction of a cross-section of the coil.

The traces 410, 430, 450 can include copper, but other conductive metals and alloys can be included. The substrates 420, 440, 460 can be a FPC, a PCB, a silicon wafer, a ceramic substrate, a dielectric substrate, or can include any other suitable material or materials. The coils can be included, for example, within a FPC or a PCB or on a dielectric substrate within an IC chip. Within an IC chip, circuit components, such as inductors, capacitors, transistors, etc., can be implemented with several metal layers, e.g., copper, and several dielectric layers, e.g., silicon oxide, deposited on top of each other to create a multilayer structure. Within the IC chip, a coil can be implemented with a dielectric substrate surrounded by metal layers on top and/or bottom of the dielectric substrate that define the traces of the coil.

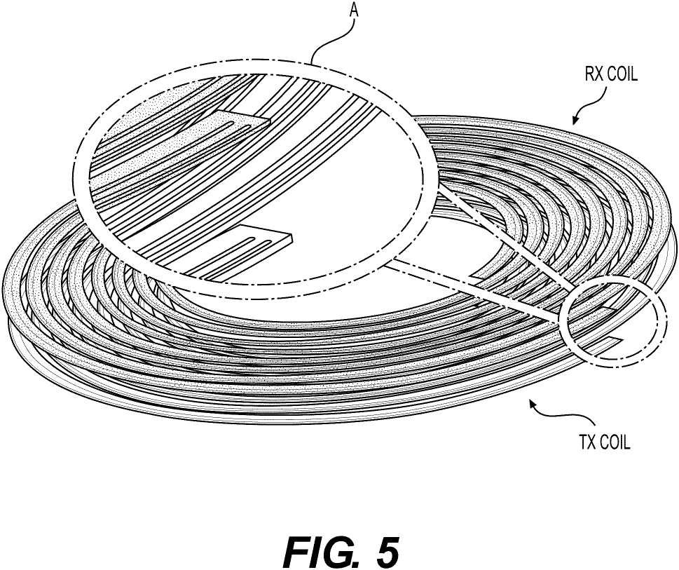

Using the present techniques, the performance of wireless charging coils on both transmitter and receiver sides can be improved by patterning the conductive material into two or more traces connected in parallel and with non-uniform widths as shown in FIG. 5. The two or more traces can extend adjacent to and parallel or substantially parallel within manufacturing tolerances to each other. FIG. 5 shows a receiving coil RX Coil and a transmitting coil TX Coil. The close-up view A in FIG. 5 shows the trace configuration of the two coils TX Coil, RX Coil with both having traces with three different widths like that shown in Example 1 in FIG. 4A. This configuration helps to achieve lower AC resistance and less generated heat, which may eliminate the need for a heatsink or an external cooling system. For circular or spiral coils (or other similar coils) in which the magnetic fields are pointed towards the center of the coil, the traces with narrower widths can be placed outside of the turn to improve performance. Alternatively, the receiving coil RX Coil and the transmitting coil TX Coil can be configured such that the outer traces are wider than the inner traces. In FIG. 5, the traces have different cross-sectional areas that are consistent along the entire length of the coils TX Coil, RX Coil, but other arrangements are also possible. The outer turns of the coil can include a single trace or traces with the same cross-sectional areas, and only the inner turns of the coil can have traces with different cross-sectional areas. For example, the coils can include a first conductor or can include first conductors with the same widths, and second conductors with different widths that are connected to the first conductor or the first conductors. That is, the number of traces in the coil can change over the length of the coil and/or the cross-sectional areas of the traces can change over the length of the coil.

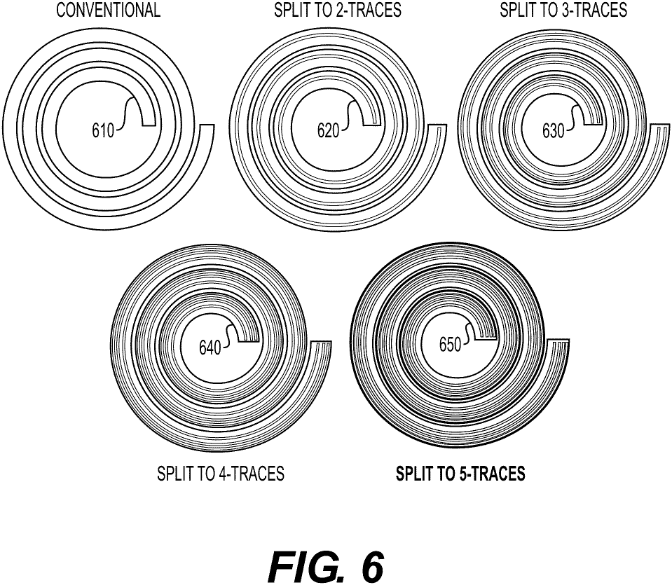

The exact number of traces depends on the application and geometry of coils. The ratio between the trace widths portions can be a function of coil geometry such as number of traces, height, and original trace width. For example, a 2:1 ratio can be used in which, in adjacent inner and outer traces, the outer trace can have a width of half or substantially half within manufacturing tolerances of the inner trace. FIG. 6 shows examples of a conventional circular spiral coil 610 with a single trace and coils with two to five different non-uniform traces respectively in coils 620, 630, 640, 650.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

What is claimed is:

1. A coil device comprising:
a substrate;
a first conductor in a first layer and including a spiral shape;
a second conductor in the first layer connected in parallel with the first conductor and extending adjacent to and parallel or substantially parallel to the first conductor;
a third conductor in a second layer connected in parallel with the first conductor and overlapping the first conductor in a plan view, the second layer is on an opposite side of the substrate as the first layer; and
a fourth conductor in the second layer connected in parallel with the third conductor and overlapping the second conductor in the plan view and extending adjacent to and parallel or substantially parallel to the third conductor; wherein
a cross-sectional area of the first conductor and a cross-sectional area of the second conductor are different.

2. The coil device according to claim 1, wherein the first conductor and the second conductor have a rectangular cross section.

3. The coil device according to claim 1, wherein the spiral shape is a circular spiral shape or a rectangular spiral shape.

4. The coil device according to claim 1, wherein
a height of the first conductor is equal to or substantially equal to a height of the second conductor, and
a width of the first conductor and a width of the second conductor are different.

5. The coil device according to claim 1, wherein a height-to-width ratio of the first conductor and a height-to-width ratio of the second conductor are different.

6. The coil device according to claim 1, wherein a cross-sectional area of the third conductor and a cross-sectional area of the fourth conductor are different.

7. The coil device according to claim 1, wherein height-to-width ratios of the first conductor and the third conductor are equal or substantially equal.

8. The coil device according to claim 1, wherein height-to-width ratios of the second conductor and the fourth conductor are equal or substantially equal.

9. The coil device according to claim 1, wherein height-to-width ratios of the first conductor and the third conductor and height-to-width ratios of the second conductor and the fourth conductor are different.

10. The coil device according to claim 1, wherein the substrate is a flexible printed circuit or a printed circuit board.

11. The coil device according to claim 1, further comprising:
a fifth conductor in the first layer, including the spiral shape, and connected to ends of the first conductor and the second conductor; and
a sixth conductor in the second layer, including the spiral shape, and connected to ends of the third conductor and the fourth conductor.

12. The coil device according to claim 1, further comprising:
a fifth conductor in the first layer, including the spiral shape, and connected to an end of the first conductor; and
a sixth conductor in the second layer, including the spiral shape, and connected to an end of the third conductor; wherein
cross-sectional areas of the fifth and the sixth conductors are identical or substantially identical.

13. An electronic device comprising the coil device according to claim 1.

14. A coil device comprising:
a substrate;
a first conductor in a first layer on the substrate and including a spiral shape; and
a second conductor in a second layer on an opposite side of the substrate as the first layer, connected in parallel with the first conductor, and overlapping or substantially overlapping all of the first conductor in a plan view, wherein
a cross-sectional shape of the first conductor and a cross-sectional shape of the second conductor are identical or substantially identical.

15. The coil device according to claim 14, wherein the substrate is a flexible printed circuit or a printed circuit board that includes the first layer and the second layer.

16. The coil device according to claim 14, further comprising:
a third conductor in the first layer connected in parallel with the first conductor and extending adjacent to and parallel or substantially parallel to the first conductor; and
a fourth conductor in the second layer connected in parallel with the second conductor and extending adjacent to and parallel or substantially parallel to the second conductor, wherein
the third conductor and the fourth conductor overlap or substantially overlap each other in the plan view.

17. The coil device according to claim 16, wherein
a cross-sectional shape of the third conductor and a cross-sectional shape of the fourth conductor are identical or substantially identical, and
the cross-sectional shape of the third conductor and the cross-sectional shape of the first conductor are different.

18. An electronic device comprising the coil device according to claim 14.

19. An electronic device comprising:
a substrate; and
a coil having a spiral shape and including:
first and second traces on a first surface of the substrate; and
third and fourth traces on a second surface of the substrate opposite to the first surface that are connected in parallel with the first and the second traces;
wherein
the first and the second traces are connected in parallel and have different cross-sectional shapes along at least a portion of a length of the coil;
the first and the third traces have identical or substantially identical cross-sectional shapes; and
the second and the fourth traces have identical or substantially identical cross-sectional shapes.

20. The electronic device of claim 19, wherein
the coil further includes:
a fifth trace on the first surface of the substrate that is connected in parallel with the first and the second traces; and
a sixth trace on the second surface of the substrate that is connected in parallel with the third and the fourth traces;
the first, the second, and the fifth traces have different cross-sectional shapes; and
the third, the fourth, and the sixth traces have different cross-sectional shapes.

21. The electronic device of claim 20, wherein widths of the first, the second, and the fifth traces increase in a width direction of a cross section of the coil.

22. (canceled)

23. The electronic device of claim 19, wherein a number of traces in the coil changes over the length of the coil and/or cross-sectional areas of the first and second traces changes over the length of the coil.
